(19) United States
(12) Patent Application Publication
(10) Pub. No.: US 2013/0233239 A1
(43) Pub. Date: Sep. 12, 2013

(54) METHOD FOR PRODUCING SILICON INGOTS

(71) Applicants: Fraunhofer-Gesellschaft zur Förderung der angewandten Forschung e. V., (US); SOLARWORLD INNOVATIONS GMBH, Freiberg/Sachsen (DE)

(72) Inventors: Daniel ORIWOL, Freiberg (DE); Matthias TREMPA, Erlangen (DE); Christian REIMANN, Munchaurach (DE)

(73) Assignees: Fraunhofer-Gesellschaft zur Förderung der angewandten Forschung e. V., Munchen (DE); SolarWorld Innovations GmbH, Freiberg/Sachsen (DE)

(21) Appl. No.: 13/785,529

(22) Filed: Mar. 5, 2013

(30) Foreign Application Priority Data
Mar. 6, 2012 (DE) 10 2012 203 524.9

(51) Int. Cl. C30B 11/14; C30B 11/02

(52) U.S. Cl. CPC C30B 11/14; C30B 11/02
USPC 117/81; 428/64.1

(57) ABSTRACT

Method for producing a silicon ingot comprising the following steps: providing a container for receiving a silicon melt with a base wall extending perpendicular to an axial direction and side walls, providing at least one flat monocrystalline seed crystal with an axial orientation selected from the group of <110>, <100> and <111> orientation, arranging the at least one seed crystal on the base wall of the container and directional solidification of a silicon melt in the container (2) to form a silicon ingot proceeding from the at least one seed crystal, wherein the axial orientation of the at least one seed crystal predetermines an axial orientation for the silicon ingot and wherein the at least one seed crystal is configured on the base wall of the container in such a way that a twin formation is avoided in an edge region adjoining the side walls.

### CROSS-REFERENCES TO RELATED APPLICATIONS

This application claims the priority of German Patent Application, Serial No. 10 2012 203 524.9, filed Mar. 6, 2012, pursuant to 35 U.S.C. 119(a)-(d), the content of which is incorporated herein by reference in its entirety as if fully set forth herein.

### FIELD OF THE INVENTION

The invention relates to a method for producing silicon ingots. The invention also relates to seed crystals for use in the production of a silicon ingot.

### BACKGROUND OF THE INVENTION

The production of silicon ingots is an important step in the production of silicon wafers, in particular for photovoltaic applications. A method for producing silicon ingots is, for example, known from US 2010/0203350 A1. There is continuously a need to develop methods of this type.

### SUMMARY OF THE INVENTION

An object of the invention is to improve a method for producing silicon ingots. This object is achieved by a method for producing a silicon ingot comprising the steps of providing a container for receiving an Si melt with, a base wall extending perpendicular to an axial direction and side walls, providing at least one flat monocrystalline seed crystal with an axial orientation selected from the group of <110>, <100> and <111> orientation, arranging the at least one seed crystal on the base wall of the container and directional solidification of a silicon melt in the container to form a silicon ingot proceeding from the at least one seed crystal, wherein the axial orientation of the at least one seed crystal predetermines an axial orientation for the silicon ingot and wherein the at least one seed crystal is configured and/or arranged on the base wall of the container in such a way that a twin formation is avoided in an edge region adjoining the side walls and extending into an interior of the container.

The core of the invention is to configure monocrystalline seed crystals and/or to arrange them on a crucible base such that a twin formation in an edge region adjoining the side walls of the crucible and extending into the interior of the crucible is avoided. According to the invention, it was recognized that the tendency to a twin formation depends on the orientation of seed crystals on the base of the crucible. There is a danger, in particular in the edge regions close to the crucible walls, in which seed crystals cannot terminate completely with the crucible, of so-called crystal twins being formed. These may have a disadvantageous effect on the crystalline structure of the silicon ingot to be produced. It was recognized according to the invention that the tendency to twin formation depends on the configuration and orientation of the seed crystals. The tendency to twin formation can be reduced or even completely avoided by a suitable configuration and/or arrangement of the seed crystals on the base wall of the container.

According to the invention, it is provided, in particular, that seed crystals with a specific orientation in an axial direction be provided and the tendency to twin formation be reduced by a suitable rotation of these seed crystals about an axis oriented in the axial direction. It was recognized according to the invention that the tendency to twin formation, in particular in the edge region of the crucible, can be reduced in that the seed crystals are rotated in such a way that the projection of their <111> lattice plane normal into a horizontal plane has a predetermined orientation relative to the lateral, in particular the outer, peripheral seed crystal edges surrounding the mono region and/or to the side walls of the crucible.

It is, in particular, advantageous if this projection onto at most 25%, in particular at most 12.5%, in particular 0% of the total length of the periphery of the entirety of the seed crystals is perpendicular to the respective closest seed crystal edge and/or side wall.

According to one aspect of the invention, the seed crystals are therefore arranged on the crucible base in such a way that the length of all the portions of the outer periphery of the entirety of the seed crystals, in which a projection of a <111> lattice plane normal of the seed crystal belonging to this portion into the horizontal is perpendicular to the outer, peripheral seed crystal edge surrounding the mono region and/or side wall, is at most 25%, in particular at most 12.5%, in particular 0% of the total length of the periphery.

The total length of the periphery corresponds here substantially to the inner periphery of the crucible. The tendency to twin formation can be reduced by an arrangement of this type of the seed crystals.

According to a further aspect of the invention, the seed crystals are configured in such a way that they have at least one horizontal seed crystal cutting face limited by cutting edges located in the horizontal, all the cutting edges in each case enclosing an angle of at most 45°, in particular at most 20°, in particular at most 5°, ideally 0°, with a projection of a <111> lattice plane normal onto the corresponding horizontal seed crystal cutting face.

The tendency to twin formation can also be reduced by this.

All the seed crystals are preferably arranged in such a way that they have a lateral <110> orientation, which, with all the side walls thereof, encloses an angle in the range of 15° to 75°, in particular in the range of 30° to 60°, in particular of about 45°. A lateral orientation is to be taken to mean an orientation parallel to the crucible base here.

All the seed crystals preferably have an axial orientation selected from the group of <110>, <100> and <111> orientations.

All the seed crystals, when using an axial <110> orientation, preferably have a lateral <110> orientation, which, with all the outer cutting edges or side walls thereof, encloses an angle not equal to 0°, in particular equal to 45°, or equal to 90°. A lateral orientation is to be taken to mean here an orientation parallel to the crucible base. The angle is, in particular, in the range of 35° to 55°.

All the seed crystals, when using an axial <100> orientation, have a lateral <110> orientation, which, with all the outer cutting edges or side walls thereof, encloses an angle not equal to 90°, preferably equal to 45°. The angle is, in particular, in the range of 35° to 55°.

All the seed crystals, when using an axial <111> orientation, preferably have a lateral <110> orientation, which, with all the outer cutting edges or side walls thereof, encloses an angle not equal to 90°, preferably equal to 15°. The angle is, in particular, in the range of 10° to 20°.

According to the invention, it may be provided that all the seed crystals have an identical lateral orientation.

However, it may also be advantageous to arrange the seed crystals in such a way that at least two adjacent seed crystals have different lateral orientations. It may, in particular, be advantageous to rotate the seed crystals, which are arranged in the corners of the crucible, about an axis running perpendicular to the crucible base in such a way that they have a different lateral orientation to their adjacent seed crystals.

It may in general be advantageous if at least one of the seed crystals, which is arranged adjacent to at least one of the side walls, has a different lateral orientation to at least one of the other seed crystals.

All the seed crystals preferably have an identical axial orientation. As a result, the crystalline structure of the silicon ingot to be produced is improved.

A further object of the invention is to improve a seed crystal for use in the production of a silicon ingot.

This object is achieved by a seed crystal for use in the production of a silicon ingot comprising a monocrystalline silicon disc with lateral cutting faces, with an axial orientation selected from the group of <110>, <100> and <111> orientation, and with a lateral <110> orientation such that the <110> orientation (17) encloses an angle in the range of 15° to 75° with the lateral cutting faces. The advantages correspond to those described above. Using a seed crystal of this type, the tendency to twin formation, in particular, can be reduced, preferably completely avoided.

Further features and details of the invention emerge from the description of a plurality of embodiments with the aid of the drawings.

### BRIEF DESCRIPTION OF THE DRAWINGS

FIG. 1 shows a schematic cross section through a crucible for producing silicon ingots with an arrangement of seed crystals on the base,

FIG. 2 shows a schematic plan view of a conventional arrangement of seed crystals with an axial <110> orientation on the base of the crucible,

FIGS. 3 to 5 show schematic plan views of arrangements according to the invention of seed crystals with axial <110> orientations on the base of the crucible,

FIG. 6 shows a view according to FIG. 2 of seed crystals with an axial <100> orientation,

FIG. 7 shows a view according to FIG. 6 with an arrangement according to the invention of seed crystals with an axial <100> orientation,

FIG. 8 shows a view according to FIG. 2 for seed crystals with an axial <110> orientation,

FIG. 9 shows a view according to FIG. 8 with an arrangement according to the invention of the seed crystals and

FIG. 10 shows a schematic perspective part view of the crucible with the seed crystals according to FIG. 2.

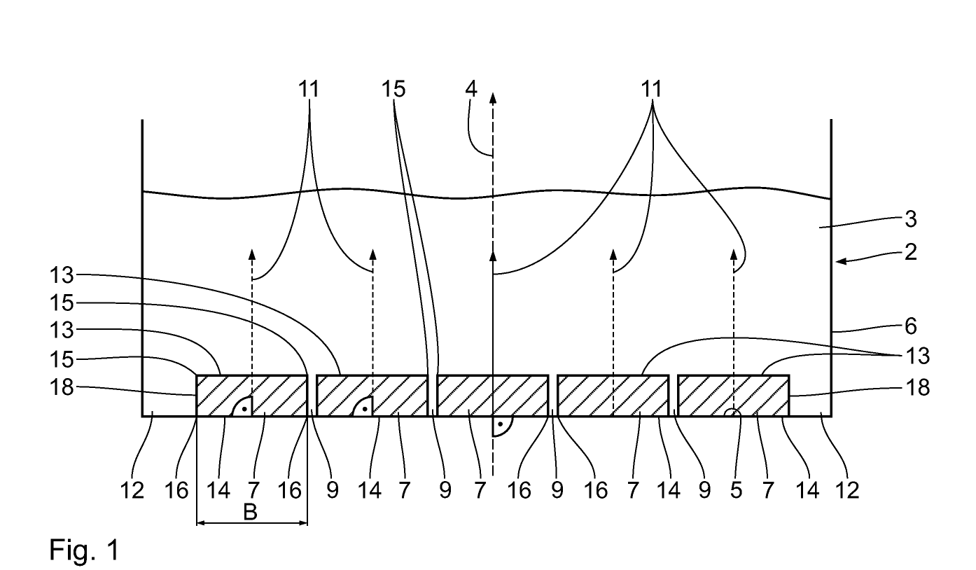

### DESCRIPTION OF THE PREFERRED EMBODIMENTS

In a method for producing silicon ingots, a container 2 configured as a crucible or mould is firstly provided to receive a silicon melt 3.

The container 2 has a base 5 extending perpendicular to a longitudinal direction 4, also called the axial direction and four side walls 6 extending at least component-wise in the longitudinal direction. The base 5 is square, i.e. the container 2 has a square cross section. It is, however, also possible to configure the container 2 with a cross section deviating from this, in particular with a round, in particular circular cross section.

A plurality of seed crystals 7 are arranged on the base 5 of the container 2. The seed crystals 7 are preferably made of a monocrystalline silicon crystal. In particular, they have no grain boundaries. In particular, they have a known crystalline structure with a known axial orientation and known lateral orientation. In this case, the axial orientation designates the orientation in the direction perpendicular to an upper and lower axial seed crystal cutting face 13, 14. The lateral orientations designate the crystalline structure of the seed crystals 7 in the direction parallel to the seed crystal cutting faces 13, 14. The axial direction corresponds to a longitudinal direction perpendicular to the base 5 of the container 2.

The seed crystal cutting faces 13, 14 are, in particular, configured parallel to one another. The seed crystals 7 are preferably configured as thin, cuboid platelets. They have, in particular, a thickness in the direction parallel to the seed crystal cutting faces 13, 14 of up to 5 cm. In the direction parallel to the seed crystal cutting faces 13, 14, they may have dimensions of at least 10 cm, in particular at least 20 cm. The seed crystal cutting faces 13, 14, in particular, have dimensions, which substantially, in each case, correspond to an integral multiple of the side lengths of wafers to be produced.

The upper axial seed crystal cutting face 13 is limited by four upper cutting edges 15. The lower axial seed crystal cutting face 14 is limited by four lower cutting edges 16.

The seed crystals 7 also have lateral cutting faces 18. These are, in particular, oriented perpendicular to the axial seed crystal cutting faces 13, 14. They are, in particular, arranged perpendicular to the base 5 of the container 2.

The seed crystals 7 are in each case separated from one another by seed crystal joints 9. The seed crystal joints 9 are, in particular, linear.

The seed crystals 7, in the direction perpendicular to the longitudinal direction 4, have a rectangular, in particular, a square cross section.

The base 5 of the container 2, apart from the seed crystal joints 9 and optionally an edge gap 12, is preferably covered with seed crystals 7 covering the surface. For this purpose, 3×3, 4×4, 5×5 or 6×6 seed crystals 7 are provided, for example. In particular, 5×5 seed crystals 7 with square cross sections are provided. However, it is also possible to use 1×5 seed crystals 7 with a rectangular, strip-like cross section for arrangement on the base 5 of the containers 2. In this case, the longer side of the seed crystals 7 preferably just corresponds to the extent of the base 5 perpendicular to the longitudinal direction 4 parallel to the side wall 6. A different number and/or arrangement of the seed crystals 7 is also possible.

The seed crystals 7 preferably have, in the direction perpendicular to the longitudinal direction 4, a width B, which just corresponds to an integral multiple of a width of columns to be sawn later from the silicon ingot, optionally increased by corresponding saw intermediate spaces. The width B of the seed crystals 7 may, in particular, substantially just correspond to the later column width. This is to be taken to mean that it deviates by a maximum of 10%, in particular a maximum of 5%, from the width of the columns to be sawn later from the silicon ingot. Accordingly, the edge gaps 12 in the direction perpendicular to the longitudinal direction 4 may have dimensions corresponding to a thickness of the side rinds to be removed.

After the arrangement of the seed crystals 7 on the base 5 of the container 2, the silicon melt 3 is provided in the container 2. For this purpose, pieced silicon may be arranged in the container 2 and melted. It is likewise possible to melt silicon in a separate container and pour it in liquid form, i.e. as a silicon melt 3, into the container 2.

In both alternatives, it is ensured by corresponding temperature guidance that the seed crystals 7 only start to melt, i.e. partially melt, but do not completely melt. The seed crystals 7 are, in particular at most 70%, in particular at most 50%, in particular at most 30%, melted in the longitudinal direction 4.

The silicon melt 3 is then solidified in a directional manner. For details of the melting of the silicon and the solidification of the silicon melt 3, reference is made to DE 10 2005 013 410 B4.

After the solidification of the silicon melt 3 to form the silicon ingot, the latter is sawn into columns with cuts parallel to the longitudinal direction 4. Side rinds in extension of the edge gaps 12 accumulate as waste here. Moreover, a base and a cap of the silicon ingot are removed as waste by cuts perpendicular to the longitudinal direction 4. The silicon ingot is sawn, in particular, in such a way that the saw cuts are located precisely in an extension of a seed crystal joint 9 in the longitudinal direction 4. As a result, the loss of high-quality silicon due to sawing is reduced.

Different arrangements according to the invention of the seed crystals will be described below with the aid of the figures.

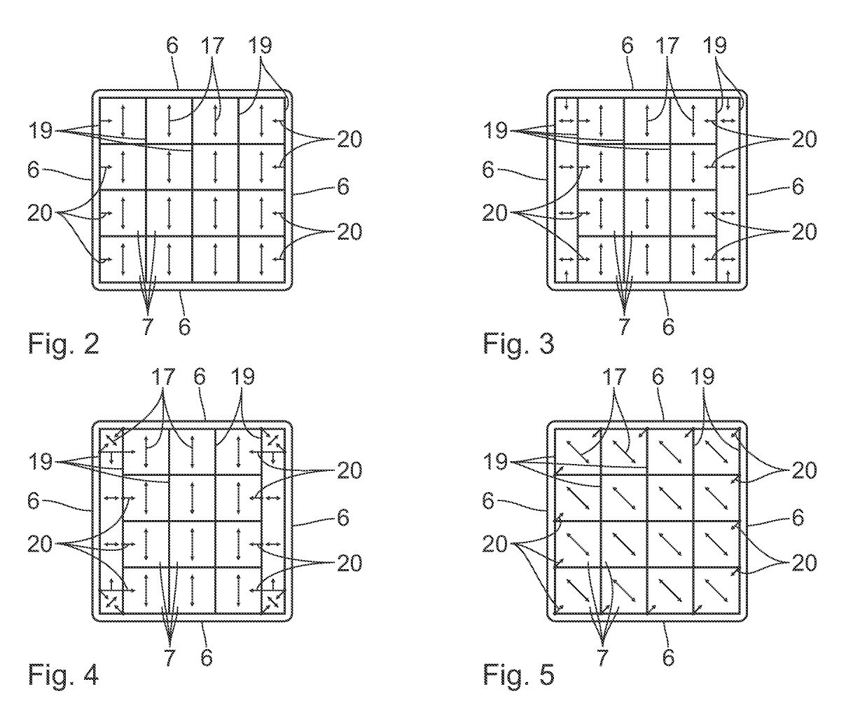

FIG. 2 shows a conventional arrangement of the seed crystals 7 with an axial <110> orientation. In order to characterize the orientation of the seed crystals 7 with regard to their lateral orientation, in other words with regard to a rotation about an axis parallel to the longitudinal direction 4, the direction of the lateral <110> orientation 17 is shown as a double arrow in FIGS. 2 to 9.

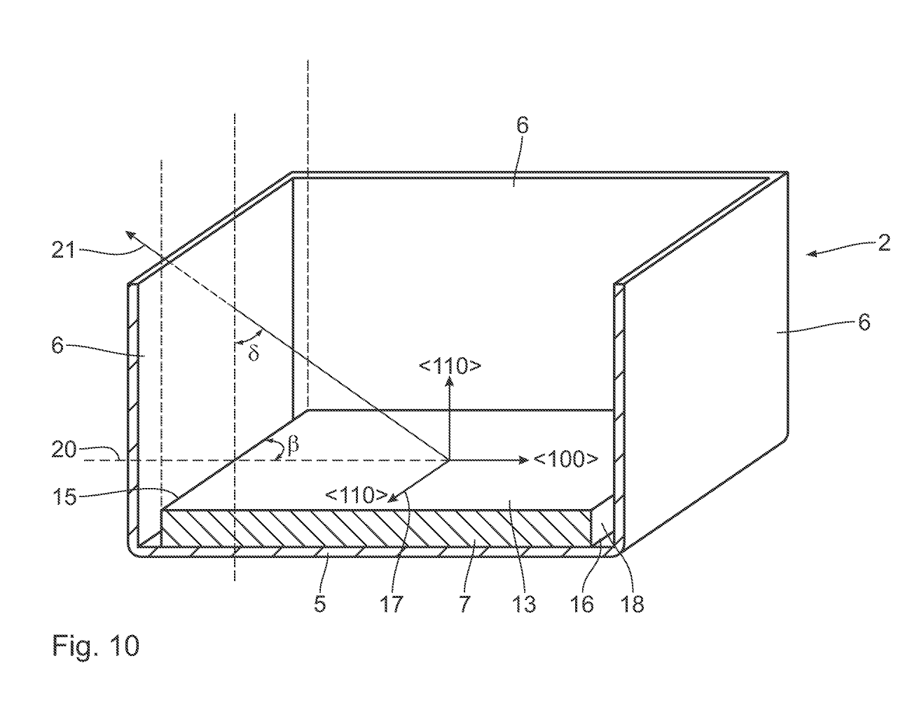

In the arrangement of the seed crystals 7 shown in FIG. 2, a {111} lattice plane has a cutting line 19 with a plane extending horizontally, in other words parallel to the base 5 and therefore parallel to the upper axial seed crystal cutting face 13. The cutting line 19 runs parallel to two opposing upper cutting edges 15 of the seed crystal 7. In the arrangement of the seed crystals 7 shown in FIG. 2, it is, in each case, parallel to the right-hand and left-hand side wall 6 of the container 2. The projection of corresponding <111> lattice plane normal 21 (cf. FIG. 10) into a horizontal plane is therefore perpendicular to the right-hand and left-hand upper cutting edge 15 or the side wall 6 of the container. This leads to an increased probability of twin formation, the twins being able to grow into the silicon ingot parallel to the projection 20 of the <111> lattice plane normal onto a horizontal plane, parallel to the {111} lattice plane.

In general, the <111> lattice plane normal 21 encloses an angle δ with the lateral cutting faces 18 or the side wall 6. The angle δ depends on the axial orientation of the seed crystals 7. The smaller this angle, the further the twin growth extends along the {111} lattice plane in the direction of the ingot centre.

In general, the projection 20 of the <111> lattice plane normal into a horizontal plane encloses an angle β with the upper cutting edges 15 or the side wall 6 or their cutting lines with the horizontal plane. If the projection of the <111> lattice plane normal 20 is perpendicular to the upper cutting edge 15 or the side wall 6 (β=90°), the probably of twin formation is greatest. In the parallel case, the probability is least (β=0°).

In seed crystals 7 with an axial <110> orientation, the {111} lattice planes are oriented parallel to the lateral <110> orientation 17. Accordingly, the cutting lines 19 are oriented parallel to the lateral <110> orientation. As emerges from FIG. 2, the sum of the length of the cutting edges 15 arranged at the edge, which run parallel to a {111} lattice plane, in this arrangement, is precisely half as great as the sum of the length of all the upper cutting edges 15 arranged at the edge. Accordingly, the sum of the length of the peripheral portions of an outer periphery of the entirety of all the seed crystals 7 in a horizontal plane, in which the projection of the <111> lattice plane normal into this horizontal plane is perpendicular to the closest side wall 6, is precisely half as great as the total length of this outer periphery.

This situation can be improved in that some of the seed crystals 7 arranged at the edge, the {111} lattice planes of which run parallel to the upper cutting edge 15 and parallel to the side wall 6, are rotated by 90° in such a way that the corresponding {111} lattice plane is perpendicular to the upper cutting edge 15 or the side wall 6. By rotating some of the seed crystals 7 arranged at the edge by 90°, the position of the horizontal cutting line 19 of the {111} lattice plane with the lateral cutting face 18 of the seed crystals 7 can be displaced into the block interior. The sum of the length of the peripheral portions, in which the projection of the <111> lattice plane normal into the horizontal plane is perpendicular to the closest upper cutting edge 15, which is parallel to the side wall 6, can be reduced by a rotation of this type. In the arrangement according to FIG. 3, it is only still 12.5% of the total length of the periphery.

In general, the seed crystals are arranged in such a way that the sum of the length of the peripheral portions, in which the projection of the <111> lattice plane normal into the horizontal plane perpendicular to the closest upper cutting edge 15, which is parallel to the side wall 6, is at most 25%, in particular at most 12.5%, in particular 0% of the total length of the periphery.

The seed crystals 7 can preferably be arranged in such a way that the ratio of the sum of the length of all the upper cutting edges 15, which are arranged at the edge and run parallel to a {111} lattice plane of the respective seed crystal 7, to the sum of the length of all the upper cutting edges 15 arranged at the edge is at most 1:4, in particular at most 1:6, in particular at most 1:8.

In this arrangement, adjacent seed crystals 7 having different lateral orientations therefore exist. In particular, one of the seed crystals 7, which are arranged adjacent to at least one of the side walls 6, has a different lateral orientation to at least one of the other seed crystals 7.

All the seed crystals 7 preferably have an identical axial orientation.

The above-mentioned ratio can be further reduced in that the seed crystals 7, which are arranged in the connection region of two side walls 6 of the container 2, i.e. in the corners of the container 2, are arranged rotated by 45° about an axis parallel to the longitudinal direction 4 relative to the adjacent seed crystals 7 (see FIG. 4). The lateral <110> direction 17 encloses an angle here of 45° with the lateral side faces 18. The lateral <110> direction 17 in particular encloses an angle of 45° with the side walls 6 of the container 2.

An arrangement of the seed crystals 7 has proven particularly advantageous, in which their lateral <110> orientation encloses an angle of 45° with all their cutting edges, in particular with all their lateral side faces 18, in particular with all the side walls 6 of the container 2 (see FIG. 5). In general, the angle, which the lateral <110> orientation encloses with the cutting edges 15 and/or the side walls 6, may be in the range of 15° to 75°.

A configuration of the seed crystal 7, in which the upper cutting edges 15 in each case enclose an angle of at least 5°, in particular at least 10°, in particular at least 15°, in particular at least 30°, preferably 45°, with the cutting lines 19, is advantageous.

Also advantageous is a configuration of the seed crystal 7, in which the projections of a <111> lattice plane normal into a horizontal plane in each case enclose an angle of at most 45°, in particular at most 30°, in particular at most 15°, in particular at most 10°, preferably 0°, with the lateral side faces 18 of the respective seed crystal 7, in particular with outer seed crystal edges on the reverse side.

Advantageously, all the seed crystals 7 have an identical lateral orientation.

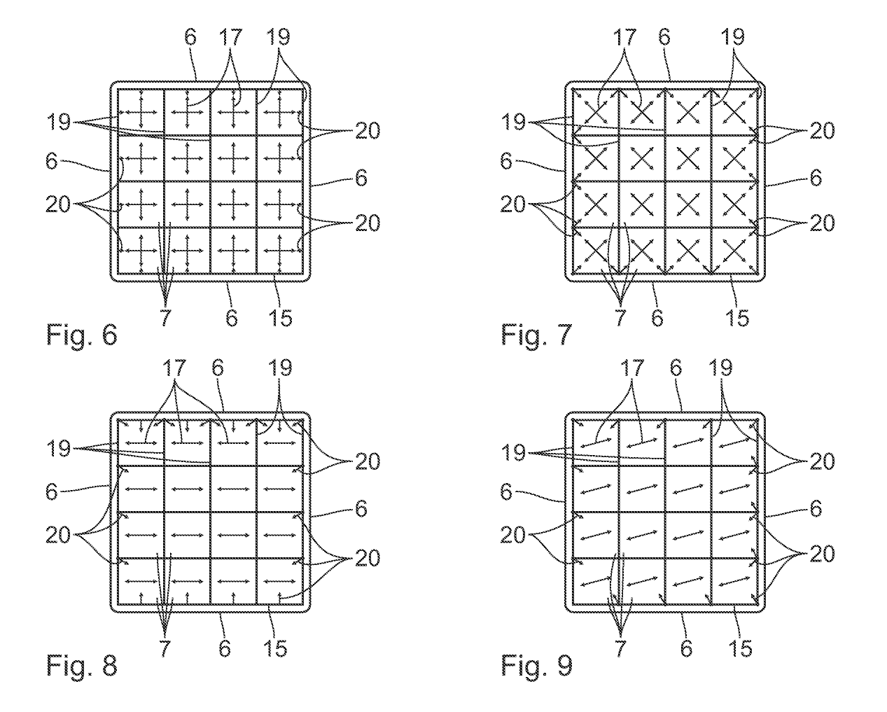

FIG. 6 shows the conventional arrangement of seed crystals 7 with an axial <100> orientation and the course of their lateral <110> orientation 17. In this arrangement, a twin formation with a growth direction projected onto a horizontal plane can occur in the entire edge region.

In order to prevent this, it is provided according to the invention that the seed crystals 7, as shown in FIG. 7, be configured in such a way that the lateral <110> orientations 17 enclose an angle of 45° with the cutting edges 15, 16, in particular with the upper cutting edges 15, in particular with the side walls 6. As a result, the possibility of a twin formation is reduced and in the event of the formation thereof, the growth direction projected on a horizontal plane is oriented such that the twin formations influence the ingot centre less.

As a result, the total length of the portions of the outer periphery of the entirety of all the seed crystals 7, in which the projection of a <111> lattice plane normal into a horizontal plane runs perpendicular to the closest upper cutting edge 15, in particular to the closest side wall 6, is significantly reduced.

In the case of seed crystals 7 with an axial <111> orientation, it is also not particularly advantageous to orient the cutting edges 15 parallel to the <110> direction 17 (see FIG. 8). In an axial orientation of this type of the seed crystals 7, three possible growth directions 20 are found for the undesired twin formation. In seed crystals 7 with an axial <111> orientation, an orientation thereof is advantageous such that their lateral <110> orientation 17 encloses an angle of 15° or 75° with one of the upper cutting edges 15 or with the side walls 6 (see FIG. 9).

What is claimed is:

1. A method for producing a silicon ingot comprising the following steps:
providing a container (2) for receiving an Si melt (3) with
a base wall (5) extending perpendicular to an axial direction and
side walls (6),
providing at least one flat monocrystalline seed crystal (7) with an axial orientation selected from the group of <110>, <100> and <111> orientation,
arranging the at least one seed crystal (7) on the base wall (5) of the container (2) and
directional solidification of a silicon melt (3) in the container (2) to form a silicon ingot proceeding from the at least one seed crystal (7),
wherein the axial orientation of the at least one seed crystal (7) predetermines an axial orientation for the silicon ingot and
wherein the at least one seed crystal (7) is at least one of configured and arranged on the base wall (5) of the container (2) in such a way that a twin formation is avoided in an edge region adjoining the side walls (6) and extending into an interior of the container (2).

2. A method according to claim 1, wherein a large number of seed crystals (7) is arranged on the base wall (5) of the container (2).

3. A method according to claim 1, wherein the seed crystals (7) are arranged in such a way that the entirety thereof, in a plane perpendicular to the axial direction, has a periphery with a total length L and in that the ratio of the sum of the length of all the portions of this periphery, in which a projection of a <111> lattice plane normal of the seed crystal (7) belonging to this portion into this plane is perpendicular to at least one of the closest upper cutting edge (15) and side wall (6), is at most 1:4 to the total length of the periphery.

4. A method according to claim 1, wherein the seed crystals (7) have at least one seed crystal cutting face (13, 14) limited by cutting edges (15, 16), all the outer cutting edges (15, 16) in each case enclosing an angle of at least 5° with a cutting line (19) of a {111} lattice plane with a corresponding seed crystal cutting face (13, 14).

5. A method according to claim 1, wherein all the seed crystals (7) are arranged in such a way that they have a lateral <110> orientation, which, with all their cutting edges (15) of the side walls (6), enclose an angle in the range of 15° to 75°.

6. A method according to claim 1, wherein all the seed crystals (7), when using an axial <110> orientation, have a lateral <110> orientation, which, with one of the group of all their outer cutting edges (15) and the side walls (6), enclose an angle not equal to 0°.

7. A method according to claim 1, wherein all the seed crystals (7), when using an axial <110> orientation, have a lateral <110> orientation, which, with one of the group of all their outer cutting edges (15) and the side walls (6), enclose an angle equal to 45°.

8. A method according to claim 1, wherein all the seed crystals (7), when using an axial <110> orientation, have a lateral <110> orientation, which, with one of the group of all their outer cutting edges (15) and the side walls (6), enclose an angle not equal to 90°.

9. A method according to claim 1, wherein all the seed crystals (7), when using an axial <100> orientation, have a lateral <110> orientation, which, with one of the group of all their outer cutting edges (15) and the side walls (6), encloses an angle not equal to 90°.

10. A method according to claim 1, wherein all the seed crystals (7), when using an axial <100> orientation, have a lateral <110> orientation, which, with one of the group of all their outer cutting edges (15) and the side walls (6), encloses an angle equal to 45°.

11. A method according to claim 1, wherein all the seed crystals (7), when using an axial <111> orientation, have a lateral <110> orientation, which, with at least one of the group of their outer cutting edges (15) and the side walls (6), encloses an angle not equal to 90° and not equal to 0°.

12. A method according to claim 1, wherein all the seed crystals (7), when using an axial <111> orientation, have a lateral <110> orientation, which, with at least one of the group of their outer cutting edges (15) and the side walls (6), encloses an angle equal to 15°.

13. A method according to claim 1, wherein all the seed crystals (7) have an identical lateral orientation.

14. A method according to claim 1, wherein at least two adjacent seed crystals (7) have different lateral orientations.

15. A method according to claim 1, wherein at least one of the seed crystals (7), which is arranged adjacent to at least one of the side walls (6), has a different lateral orientation to at least one of the other seed crystals (7).

16. A method according to claim 1, wherein all the seed crystals (7) have an identical axial orientation.

17. A method according to claim 1, wherein the seed crystals (7) have at least one axial seed crystal cutting face (13, 14) limited by cutting edges (15, 16), the at least one axial seed crystal cutting face (13, 14) having dimensions, which in each case substantially correspond to an integral multiple of side lengths of wafers to be produced.

18. A seed crystal (7) for use in the production of a silicon ingot comprising a monocrystalline silicon disc
a. with lateral cutting faces (18),
b. with an axial orientation selected from the group of <110>, <100> and <111> orientation, and
c. with a lateral <110> orientation (17) such that the <110> orientation (17) encloses an angle in the range of 15° to 75° with the lateral cutting faces (18).
